(19) United States
(12) Patent Application Publication
(10) Pub. No.: US 2025/0300149 A1
(43) Pub. Date: Sep. 25, 2025

(54) 3DIC PACKAGING WITH EFFICIENT HEAT DISSIPATION

(71) Applicants: Taiwan Semiconductor Manufacturing Co., Ltd., Hsinchu (TW); TSMC Arizona Corporation, Phoenix, AZ (US)

(72) Inventors: Xuewen TANG, Hsinchu (TW); Ji-Feng YING, Hsinchu (TW); Wen-Hsien CHUANG, Hsinchu (TW); Huei-Wen YANG, Hsinchu (TW)

(21) Appl. No.: 18/799,826

(22) Filed: Aug. 9, 2024

Related U.S. Application Data
(60) Provisional application No. 63/569,607, filed on Mar. 25, 2024.

(51) Int. Cl. H01L 25/18; H01L 23/00; H01L 23/373; H01L 23/48; H01L 23/538; H10B 80/00

(52) U.S. Cl. CPC H01L 25/18; H01L 23/3738; H01L 24/08; H01L 24/32; H01L 24/80; H01L 24/83; H01L 23/481; H01L 23/5383; H01L 24/81; H01L 2224/08146; H01L 2224/32227; H01L 2224/80895; H01L 2224/80896; H01L 2224/81986; H01L 2224/83986; H10B 80/00

(57) ABSTRACT

An integrated circuit package includes a substrate, a semiconductor interposer on the substrate, and an integrated circuit die, including a plurality of transistors, on the interposer. A carrier die is coupled to a top surface of the integrated circuit die. The integrated circuit die includes a plurality of top metal structures at a top surface of the integrated circuit die. The carrier die includes a plurality of dummy contact pads. The carrier die is bonded to the integrated circuit die by a bonding layer such that each dummy contact is positioned directly over one or more of the top metal structures with the bonding layer between them.

### BACKGROUND

The semiconductor integrated circuit industry has experienced exponential growth. Technological advances in integrated circuit materials and design have produced generations of integrated circuits where each generation has smaller and more complex circuits than the previous generation. In the course of integrated circuit evolution, functional density (i.e., the number of interconnected devices per die area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing integrated circuits.

With this scaling down of integrated circuit features, various efforts have also been made to address issues associated with packaging of integrated circuits. In some cases, an integrated circuit package includes a substrate, one or more integrated circuit dies, and an interposer between the substrate and the integrated circuit dies. However, there are many difficulties associated with such packaging that can result in scrapped wafers or other drawbacks.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is an illustration of an integrated circuit package, in accordance with some embodiments.

FIG. 1B is a top view of a carrier die of the integrated circuit package of FIG. 1A, in accordance with some embodiments.

FIGS. 2A-2M are views of an integrated circuit package at various stages of processing, in accordance with some embodiments.

FIG. 3 is an illustration of an integrated circuit package, in accordance with some embodiments.

FIG. 4 is an illustration of an integrated circuit package, in accordance with some embodiments.

FIG. 5 is a flow diagram of a method, in accordance with some embodiments.

FIG. 6 is a flow diagram of a method, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Terms indicative of relative degree, such as “about,” “substantially,” and the like, should be interpreted as one having ordinary skill in the art would in view of current technological norms.

Embodiments of the present disclosure provide an integrated circuit package with improved heat dissipation. The integrated circuit package includes an integrated circuit die positioned on top of an interposer. The interposer, in turn, is positioned on a substrate. One or more memory dies are also positioned on either the interposer or the substrate. The integrated circuit die includes a plurality of transistors that, in operation, may generate a large amount of heat. The integrated circuit die includes front side metal interconnection structures includes conductive vias and metal lines above the transistors. The integrated circuit die includes backside metal interconnection structures including conductive vias and metal lines below the transistors. The front side of backside metal interconnection structures are electrically connected by one or more through vias. The front side interconnection structures include a top metal layer patterned as a plurality of contact pads. In order to facilitate heat dissipation, the package includes a carrier die and coupled to a top surface of the front side of the integrated circuit. The carrier die includes a plurality of dummy contact pads positioned directly above the contact pads of the front side of the integrated circuit die. The carrier die is thinned so that the thickness of the carrier die corresponds to the thickness of the dummy contact pads. A nonconductive bonding layer is positioned between the integrated circuit die and the carrier die.

The presence of the carrier die and the dummy contact pads results in greatly improved heat dissipation. Heat from the transistors of the integrated circuit die flows upward through the front side metal interconnections to the contact pads. The heat flows to the dummy contact pads of the carrier die and is effectively dissipated from the dummy contact pads. Heat also dissipates to a lesser extent through the backside metal interconnections. However, the presence of the front side interconnections and the dummy contact pads of the carrier die results in highly effective upward heat dissipation from the transistors. This reduces the possibility of damage to components of the package. This also provides higher performance for the transistors and other components of the package. This also results in higher package yields and fewer scrapped packages.

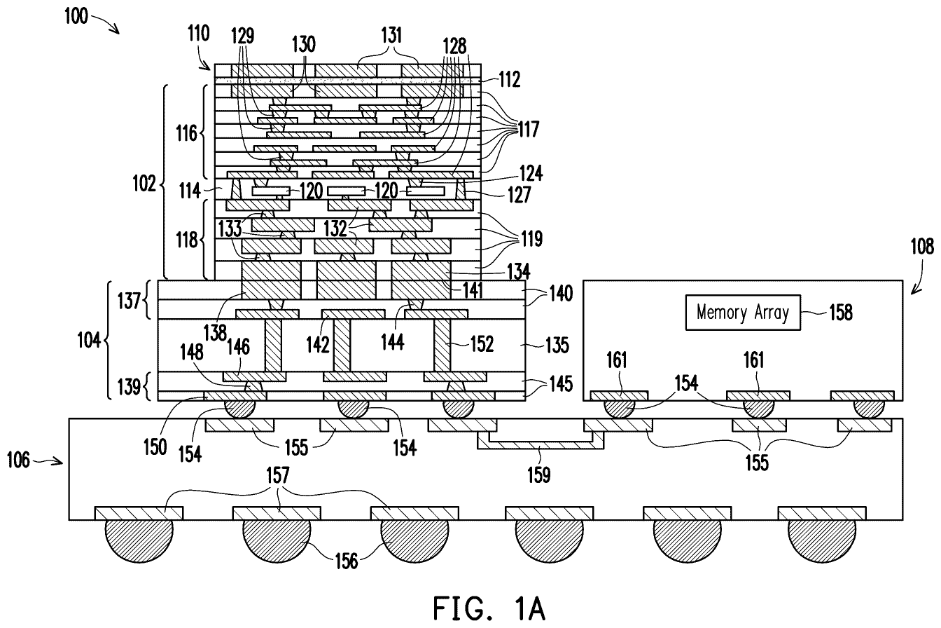

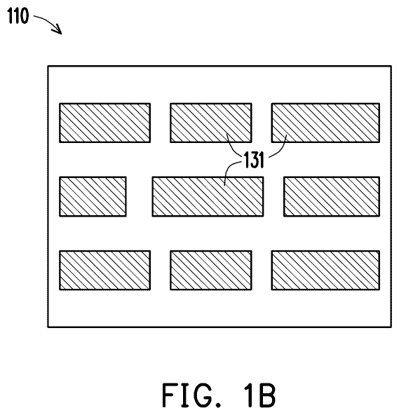

FIG. 1A is an illustration of an integrated circuit package 100, in accordance with some embodiments. The components of the integrated circuit package 100 include an integrated circuit die 102, an interposer 104, a substrate 106, a second integrated circuit die 108, and a carrier die 110. As will be set forth in more detail below, the components and arrangement of components of the integrated circuit package 100 promote effective heat dissipation within the integrated circuit package 100.

The integrated circuit die 102 includes an active device region 114, a front side 116 above the active device region 114, and a backside 118 below the active device region 114. The integrated circuit die 102 can correspond to a processor, a microcontroller, a logic circuit, or other types of circuits. The integrated circuit die 102 may correspond to a system on chip die (SoC) or other type of integrated circuit die.

The active device region 114 includes a plurality of transistors 120. The transistors 120 may be formed in conjunction with a semiconductor substrate or one or more semiconductor layers of the active device region 114. The transistors 120 can include gate all around transistors each having a plurality of stacked channels with a gate metal wrapped around each of the stacked channels. The transistors 120 can include FinFET transistors. The transistors 120 can include other types of transistors. The transistors 120 can include source/drain regions, gate electrodes, source/drain contacts, and other components. The transistors 120 can be arranged in complex circuit architectures resulting in processing circuits, logic circuits, or other types of circuits capable of complex operations.

The active device region 114 includes a plurality of top conductive vias 124. The top conductive vias 124 contact top side structures of the transistors 120. The top conductive vias 124 can include source/drain contacts, gate contacts, or other types of metal structures. The top conductive vias 124 electrically connect the transistors 120 to metal interconnection structures of the front side 116.

The active device region 114 includes a plurality of bottom conductive vias 126. The bottom conductive vias 126 contact bottom structures of the transistors 120, or contact structures of the transistors 120 via extending upward to upper structures of the transistors 120. The bottom conductive vias 126 can include source/drain contacts, gate contacts, or other types of metal structures. The bottom conductive vias 126 electrically connect the transistors 120 to metal interconnection structures of the backside 118.

In some embodiments, the top conductive vias 124 are laterally wider and or vertically thicker than the bottom conductive vias 126. This can help the top conductive vias 124 preferentially conduct heat upward from the transistors 120 to the front side 116. In some embodiments, the top conductive vias 124 include tungsten or another highly conductive material. In some embodiments, the bottom conductive vias 126 include molybdenum or ruthenium. Accordingly, in some embodiments, the top conductive vias 124 include a different material than the bottom conductive vias 126. Alternatively, the top conductive vias 124 and the bottom conductive vias 126 can include a same material and can include materials other than those described above.

In operation, the transistors 120 can generate large amounts of heat. Heat is generated as the transistors 120 are operated at high switching speeds during which the transistors are turned on and off. The relatively small currents may flow through each individual transistor 120. The presence of a large number of transistors 120 (millions or billions of transistors, in some embodiments) operated at high switching speeds may result in generation of relatively large amounts of heat. In practice, the hottest portion of the integrated circuit package 100 may be the active device region 114.

Heat from the transistors 120 may flow or dissipate both upward and downward (and laterally). In practice, a large amount of heat may flow upward into the front side 116. A relatively small amount of heat may flow downward into the backside 118. As will be described in more detail below, heat may flow from the front side to the backside by way of through vias extending through the active device region 114 between the front side 116 and the backside 118. However, a more efficient path of travel for the heat is to dissipate upward through the front side 116, as will be set forth in more detail below.

The front side 116 includes a plurality of stacked dielectric layers 117. Metal interconnection structures are formed in the stack of dielectric layers 117. The metal interconnection structures include a plurality of metal lines 128 and conductive vias 129. More particularly, each dielectric layer 117 may include a layer of metal lines 128 formed therein and a plurality of conductive vias 129 landing on the metal lines 128 of that later. The lowest layer of metal lines 128 are in direct contact with the top conductive vias 124 connected to the transistors 120 of the active device region 114. The lowest layer of metal lines 128 may be termed metal 0 or M0. A next layer of metal lines 128 is formed in the next interlevel dielectric layer 117 and may correspond to metal 1 or M1, with corresponding conductive vias 129 landing thereon. FIG. 1A illustrates six layers of metal lines 128 (e.g., M0-M5) each formed in a dielectric layer 117. In practice, each dielectric layer 117 may include multiple dielectric sub-layers.

In some embodiments, the metal lines 128 include one or more of tungsten, aluminum, titanium, titanium nitride, tantalum, tantalum nitride, or other suitable conductive materials. The conductive vias 129 include one or more of aluminum, titanium, titanium nitride, tantalum, tantalum nitride, or other suitable conductive materials. Each dielectric layer 117 can include one or more layers of one or more of SiO, SiN, SiON, SiOCN, SiOC, SiCN, AlO, or other suitable dielectric materials.

The front side 116 includes a top metal layer including top metal structures 130. In practice, the top metal structures 130 may be formed of a different material than the metal lines 128. In one example, the top metal structures 130 include copper. Alternatively, the top metal structures 130 can include the same metal or materials as the metal lines 128. The top metal structures 130 may be substantially thicker than the metal lines 128. The bottom surface of each metal structure 130 may be in contact with a conductive via 129 of a next lower layer.

In some embodiments, the top dielectric layer 117 corresponds to a passivation layer of the integrated circuit die 102. The passivation layer can include SiN, SiON, SiOCN, SiOC, SiCN, or other suitable dielectric layers. While FIG. 1A illustrates the passivation layer as a single passivation layer, in practice, the passivation layer can include multiple layers.

In some embodiments, the top metal structures 130 correspond to inactive contact pads of the integrated circuit die 102. However, the contact pads are inactive in the sense that they are not physically contacted from above by electrical components external to the integrated circuit die 102. In this sense, the top metal structures 130 may correspond to dummy contact pads. As will be described in more detail below, the integrated circuit package 100 utilizes the top metal structures 130, in conjunction with the carrier die 110, to effectively dissipate heat from the transistors 120.

The package 100 includes a carrier die 110 positioned on top of the front side 116 of the integrated circuit die 102. The carrier die 110 is bonded to the front side 116 of the integrated circuit die 102 by bonding layer 112. The bonding layer 112 is in direct physical contact with the top surfaces of the top metal structures 130 of the front side 116. The bonding layer 112 includes a material that is not electrically conductive so as to not electrically short all of the top metal structures 130. In some embodiments, the bonding layer 112 includes silicon oxide. However, other the bonding layer 112 can include other dielectric materials without departing from the scope of the present disclosure.

In some embodiments, the carrier die 110 is a semiconductor die. The carrier die 110 can include silicon, silicon germanium, or other suitable semiconductor materials. Alternatively, the carrier die 110 can include a dielectric material or other types of material.

The carrier die 110 includes a plurality of metal structures 131 embedded therein. In some embodiments, the metal structures 131 are dummy contact pads having the shade, material, thickness utilized in contact pads. The metal structures 131 one may be termed dummy contact pads because the metal structures 131 are not, in some embodiments, electrically connected to external structures. For example, operational contact pads may typically be connected to solder bumps, solder balls, reflow layers, bonding wires, or other conductive structures that electrically connect the contact pad to an external device. However, in some embodiments, the dummy contact pads are not in contact with any such structures. Instead, the function of the dummy contact pads is to enhance heat dissipation from the front side 116, as will be set forth in more detail below.

In some embodiments, each metal structure 131 of the carrier die 110 is positioned directly over a corresponding top metal structure 130 of the front side 116 of the integrated circuit die 102. As heat flows upward through the metal interconnection structures 116, the heat may eventually flow from the top metal structures 130 across the thin bonding layer 112 to the metal structures 131 of the carrier die 110. Because each metal structure 131 is directly above a metal structure 130, heat can effectively flow from the top metal structures 130 to the metal structures 131 of the carrier die 110.

In some embodiments, the carrier die 110 has a total vertical thickness substantially identical to the vertical thickness of the metal structures 131. As will be described in more detail for the below, after formation of the metal structures 131 and the carrier die 110, the thickness of the carrier die 110 is reduced to be substantially equal to the thickness of the metal structures 131. Accordingly, a top surface of the metal structures 131 is substantially coplanar with a top surface of the carrier die 110. A bottom surface of the metal structures 131 is substantially coplanar with a bottom surface of the carrier die 110.

In some embodiments, the pattern of the metal structures 131 one is substantially identical to the pattern of the top metal structures 130 of the front side 116. In other words, each metal structure 131 is positioned directly above a corresponding top metal structure 130 and has substantially identical lateral dimensions of the corresponding top metal structure 130. Accordingly, a mask can be utilized to pattern the top of the structures 130 and the metal structures 131.

In some embodiments, the metal structures 131 have a different pattern than the top structures 130. For example, the metal structures 131 may have larger surface areas, smaller surface service, different shapes, and different patterns and configurations than the top metal structures 130. Various configurations of the metal structures 131 and the top metal structures 130 can be utilized without departing from the scope of the present disclosure.

The back side 118 includes a plurality of stacked dielectric layers 119. Metal interconnections structures are formed in the stack of dielectric layers 119. The metal interconnection structures include a plurality of metal lines 132 and conductive vias 133. More particularly, each dielectric layer 119 may include a layer of metal lines 132 formed therein and a plurality of conductive vias 133 landing on the metal lines 132 of that layer. The highest layer of metal lines 132 are in direct contact with the bottom conductive vias 126 connected to the transistors 120 of the active device region 114. The highest layer of metal lines 132 may be termed metal 0 or M0 of the backside. A next layer of metal lines 132 is formed in the next interlevel dielectric layer 119 and may correspond to metal 1 or M1 of the backside, with corresponding conductive vias 133 landing thereon. FIG. 1A illustrates three layers of metal lines 132 (e.g., backside M0-M2) each formed in a dielectric layer 119. In practice, each dielectric layer 119 may include multiple dielectric sub-layers.

In some embodiments, the metal lines 132 include one or more of tungsten, aluminum, titanium, titanium nitride, tantalum, tantalum nitride, or other suitable conductive materials. The conductive vias 133 include one or more of aluminum, titanium, titanium nitride, tantalum, tantalum nitride, or other suitable conductive materials. Each dielectric layer 119 can include one or more layers of one or more of SiO, SiN, SiON, SiOCN, SiOC, SiCN, AlO, or other suitable dielectric materials.

The back side 117 includes a bottom metal layer including bottom metal structures 134. In practice, the bottom metal structure 134 may be formed of a different material than the metal lines 132. In one example, the bottom metal structures 134 include copper. Alternatively, the bottom metal structures 134 can include the same metal or materials as the metal lines 132. The bottom metal structure 134 may be substantially thicker than the metal lines 132. The bottom surface of each metal structure 134 may be in contact with a conductive via 133 of a higher layer.

In some embodiments, the bottom dielectric layer 119 corresponds to a passivation layer of the integrated circuit die 102. The passivation layer can include SiN, SiON, SiOCN, SiOC, SiCN, or other suitable dielectric layers. While FIG. 1A illustrates the passivation layer as a single passivation layer, in practice, the passivation layer can include multiple layers.

In some embodiments, the bottom metal structures 134 correspond to bottom contact pads of the integrated circuit die 102. As will be described in more detail below, the bottom metal structures 134 are connected to corresponding conductive structures of the interposer 104 by hybrid bonds 141.

In some embodiments, because the top conductive structures 130 of the front side 116 are not electrically connected to the external device, a higher density of bottom metal structures 134 is called for to electrically connect to the interposer 104. This is because both the front side interconnections and the backside interconnections will be electrically connected to the interposer 104. Accordingly, in some embodiments, a hybrid bond 141 is utilized to electrically connect each bottom metal structure 134 to a corresponding top metal structure 138 of the interposer 104. The hybrid bond enables a much higher density of connections between the backside 118 and the interposer 104 than solder bumps or other types of connections.

The hybrid bonds 141 are formed by performing a hybrid bonding process. In some embodiments, the hybrid bonding process includes slightly recessing the surface metal structures relative to a surrounding dielectric material, such as silicon oxide or another suitable dielectric material. This is performed for both dies for which the hybrid bonding process will be performed. The two dies are then pressed together face-to-face so that the recessed surface metal structures aligned with each other. A thermal annealing process is then performed in which the two dies are slowly heated. This causes the metal material of the opposing surface metal structures to expand the cross the gap. The result is that the opposing surface metal structures physically contact each other, thereby forming a physical and electrical connection. Accordingly, some embodiments, the hybrid bond 141 corresponds to direct physical contact of the opposing surface metal structures. In some embodiments, the opposing surface metal structures are each made of copper, though other materials can be utilized without departing from the scope of the present disclosure.

The interposer 104 may correspond to a semiconductor integrated circuit die or semiconductor die. The interposer 104 includes a semiconductor substrate 135. The interposer 104 includes a frontside dielectric stack 137 on the semiconductor substrate 135. The interposer 104 includes a backside dielectric stack 139 below the substrate.

The semiconductor substrate 135 can include silicon, silicon germanium, or other suitable semiconductor materials. Though not shown in FIG. 1A, in some embodiments transistors can be formed in conjunction with the semiconductor substrate 135.

In some embodiments the front side dielectric stack 137 corresponds to a plurality of interlevel dielectric layers 140 formed above the semiconductor substrate 135. The interlevel dielectric layers 140 can include one or more of SiO, SiN, SiON, SiOCN, SiOC, SiCN, AlO, or other suitable dielectric materials.

A plurality of metal lines 142 are formed in the front side dielectric stack 137. Each interlevel dielectric layer 140 (or set of interlevel dielectric layers 140) can include a layer of metal lines 142 embedded therein. Additionally, conductive vias 144 can land on the metal lines 142. While FIG. 1A illustrates only a single layer of metal lines 142, in practice, multiple layers of metal lines 142 may be included in a similar manner as the front-end 116 of the integrated circuit die 102. In an exemplary embodiment, the metal lines 142 include copper. However, the metal lines 142 can include tungsten, aluminum, titanium, titanium nitride, tantalum, tantalum nitride, or other suitable conductive materials. The conductive vias 144 can include copper, tungsten, aluminum, titanium, titanium nitride, tantalum, tantalum nitride, or other suitable conductive materials.

The front side dielectric stack 137 includes top metal structures 138 in a top dielectric layer 140. The top dielectric layer 140 correspond to a passivation layer or a set of passivation layers. The passivation layer can include one or more of SiO, SiN, SiON, SiOCN, SiOC, SiCN, AlO, or other suitable dielectric materials. The top metal structures 138 can include one or more of copper, tungsten, aluminum, titanium, titanium nitride, tantalum, tantalum nitride, or other suitable conductive materials. As described previously, the top metal structures 138 are electrically connected to bottom metal structures 134 of the backside 118 of the integrated circuit die 102 by hybrid bonds 141.

In some embodiments the backside dielectric stack 139 corresponds to a plurality of interlevel dielectric layers 145 formed below the semiconductor substrate 135. The interlevel dielectric layers 145 can include one or more of SiO, SiN, SiON, SiOCN, SiOC, SiCN, AlO, or other suitable dielectric materials.

A plurality of metal lines 146 are formed in the backside dielectric stack 139. Each interlevel dielectric layer 145 (or set of interlevel dielectric layers 145) can include a layer of metal lines 146 embedded therein. Additionally, conductive vias 148 can land on the metal lines 146. While FIG. 1A illustrates only a single layer of metal lines 146, in practice, multiple layers of metal lines 146 may be included in a similar manner as the front-end 116 of the integrated circuit die 102. In an exemplary embodiment, the metal lines 146 include copper. However, the metal lines 146 can include tungsten, aluminum, titanium, titanium nitride, tantalum, tantalum nitride, or other suitable conductive materials. The conductive vias 148 can include copper, tungsten, aluminum, titanium, titanium nitride, tantalum, tantalum nitride, or other suitable conductive materials.

The backside dielectric stack 139 includes bottom metal structures 150 in a bottom dielectric layer 145. The bottom dielectric layer 145 correspond to a passivation layer or a set of passivation layers. The passivation layer can include one or more of SiO, SiN, SiON, SiOCN, SiOC, SiCN, AlO, or other suitable dielectric materials. The bottom metal structures 150 can include one or more of copper, tungsten, aluminum, titanium, titanium nitride, tantalum, tantalum nitride, or other suitable conductive materials.

Returning to the semiconductor substrate 135, the semiconductor substrate 135 can include a plurality of through silicon vias (TSVs) 152. Each TSV 152 extends between a metal line 142 of the front side dielectric stack 137 and the metal line 146 of the backside dielectric stack 139. In this manner, the TSVs 152 electrically connect interconnection structures of the front side dielectric stack 137 to interconnection structures of the backside dielectric stack 139.

The substrate 106 can include a package substrate such as a PCB substrate, an organic substrate, or other types of substrates. The substrate 106 can include a plurality of top metal structures 155. The top metal structures 155 facilitate electrical connection to the interposer 104. In particular, each bottom metal structure 150 of the interposer 104 is coupled to a corresponding top metal structure 155 of the substrate 106 by external interconnection structures 154. The external interconnection structures 154 can include C4 copper bumps, solder bumps, or other types of conductive structures.

In some embodiments, the substrate 106 includes bottom metal structures 157 on a bottom surface of the substrate 106. Though not shown in FIG. 1A, the substrate 106 can include package traces or other internal interconnect structures that provide electrical connection between top metal structures 155 and the bottom metal structures 157. Package balls 156 can be coupled to the bottom of the substrate 106 to enable electrical connection to a circuit board on which the package 100 can be mounted. Various other conductive structures can be utilized without departing from the scope of the present disclosure. The package balls 156 can correspond to a ball grid array.

FIG. 1A illustrates a metal interconnection structure 159 electrically connecting one or more top metal structures 155 electrically coupled to the interposer 104 to top metal structures 155 electrically connected to the second integrated circuit die 108. In some embodiments, the second integrated circuit die is a memory die. The metal interconnect structure 159 can include a plurality of metal lines, conductive vias, signal traces, or other types of interconnection structures. This enables communication between the integrated circuit die 102 and the integrated circuit die 108 via the substrate 106. As will be described in more detail below, in some embodiments, the integrated circuit die 108 is positioned on a top surface of the interposer 104 rather than on a top surface of the substrate 106. The metal interconnection structure 159 can be placed in a very tight pitch between the interposer 104 and the integrated circuit die 108. The integrated circuit die 108 can be connected to the integrated circuit 102 via either the interposer 104 or the substrate 106 with localized silicon or embedded silicon bridge.

The integrated circuit die 108 includes a memory array 158. The memory array 158 can correspond to an array of dynamic random-access memory (DRAM) cells, static random-access memory (SRAM) cells, flash memory cells, or other types of memory cells. In an exemplary embodiment, the memory array 158 includes a DRAM array. The integrated circuit die 108 can include a plurality of individual stacked memory dies each including a portion of the memory array 158. The integrated circuit die 108 can include bottom metal structures 161 each coupled to an external interconnection structure 154.

After assembly of the integrated circuit package 100, the integrated circuit package 100 can be mounted on a circuit board of an electronic device. The surface level interconnection structures on the bottom of the substrate 106 can be coupled to corresponding structures on the circuit board. Signals can be passed from the circuit board through the substrate 106 to the integrated circuit die 102 and the integrated circuit die 108. Similarly, signals can be passed from the integrated circuit die 102 and the integrated circuit die 108 through the substrate 106 to the circuit board.

Though not shown in FIG. 1A, in some embodiments, a plurality of integrated circuit dies 102 can be positioned on the interposer 104. Each integrated circuit die 102 can be coupled to a carrier die 110 including metal structures 131 for improved heat dissipation.

Though not shown in FIG. 1A, after assembly of the components of the integrated circuit package 100, encapsulation can be performed. In other words, the integrated circuit package 100 can include an encapsulation on the substrate surrounding the interposer 104, the integrated circuit die 102, and the integrated circuit die 108. The encapsulation can be in direct contact with the top surfaces of the metal structures 131 of the carrier die 110. The encapsulation can include one or more of a molding compound, a dielectric housing, or other structures to protect the integrated circuit die 102, the interposer 104, and the integrated circuit die 108.

Principles of the present disclosure can extend to various types of integrated circuit packages. Accordingly, the integrated circuit package 100 can include an interposer-based package, a local silicon interconnect (LSI) based package, an integrated fan out (InFO) based package, a chip on the wafer on substrate (CoWoS) based package, a system on integrated chip (SoIC) based package, a wafer on wafer (WoW) based package, or other types of packages.

FIG. 1B is a top view of the carrier die 110, in accordance with some embodiments. The top view of the carrier die 110 illustrates the shapes and positions of the top metal structures 131. As set forth previously, in some embodiments, the layout of the top metal structures 131 may be substantially identical to the layout of the top metal structures 130 of the integrated circuit die 102. Alternatively, some embodiments, the layouts of the top metal structures 131 may be different than the layout of the top metal structures 130.

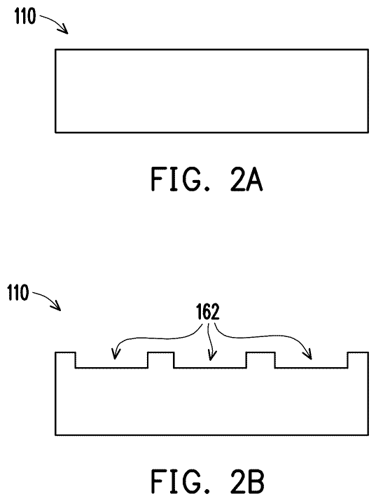

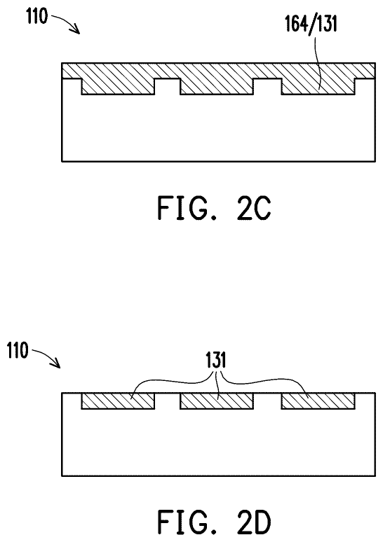

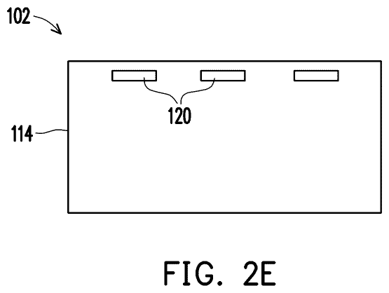

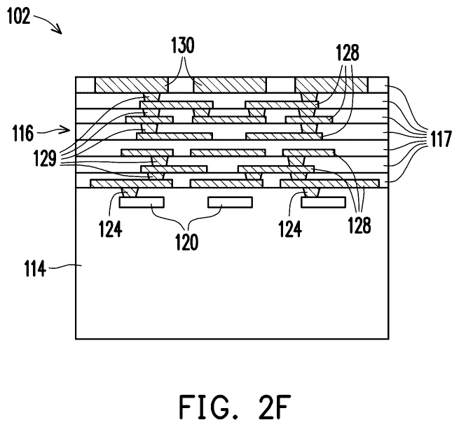

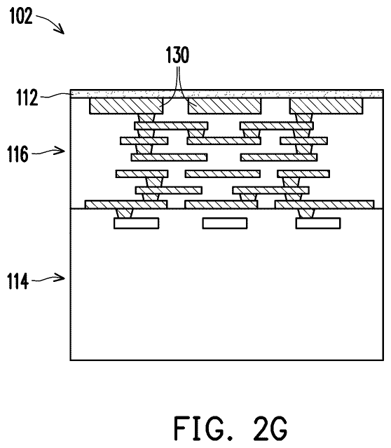

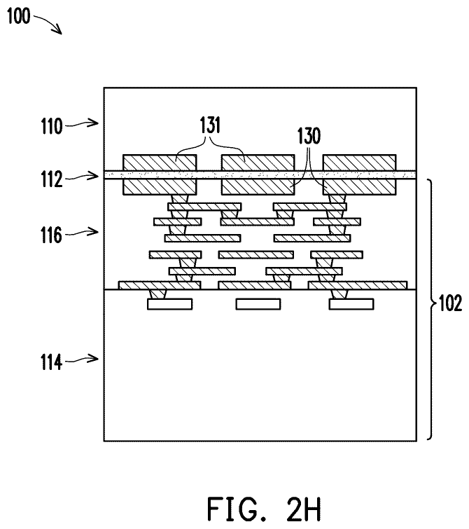

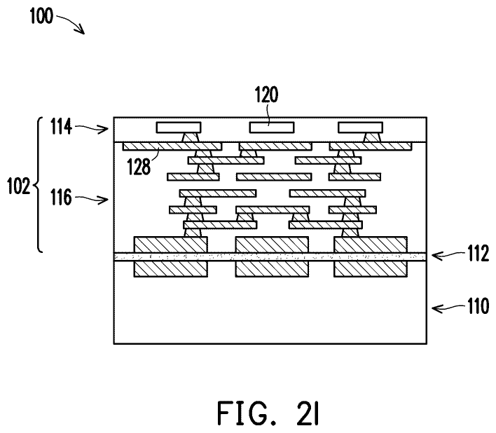

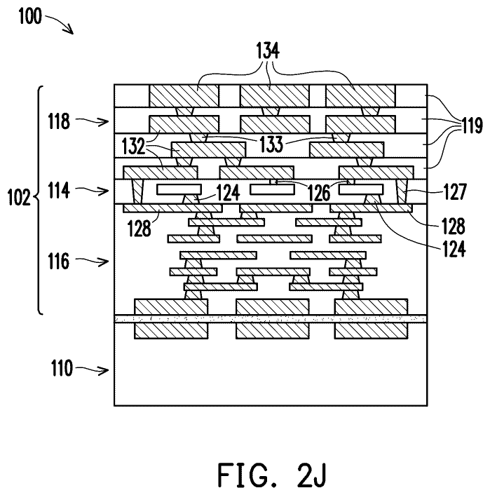

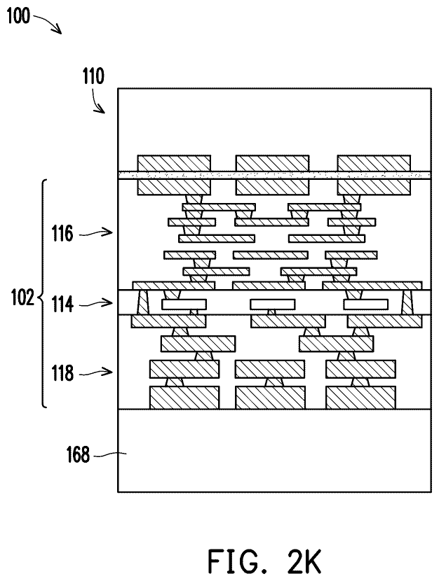

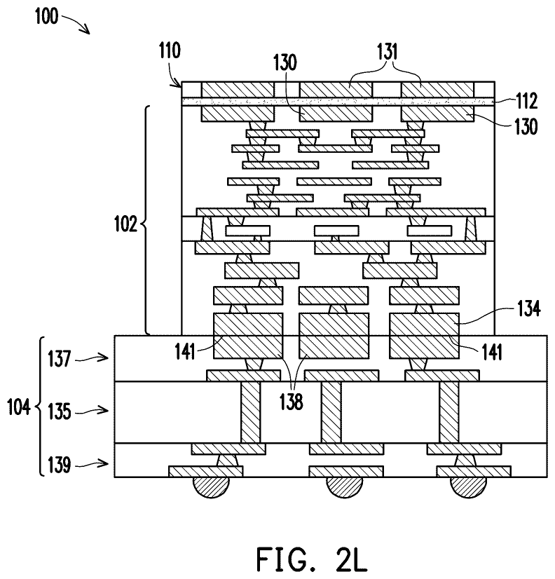

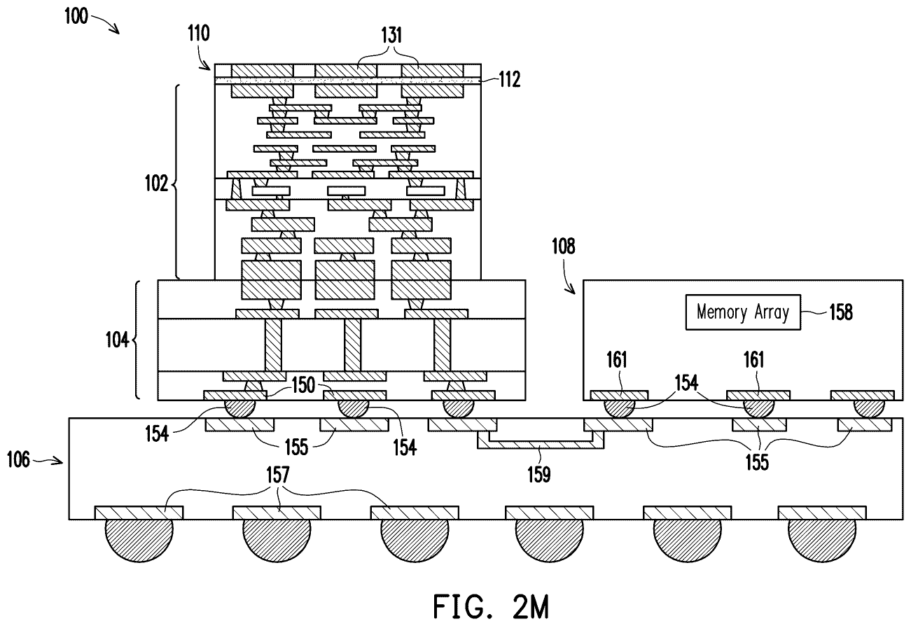

FIGS. 2A-2M are views of components of an integrated circuit package 100 at various stages of assembly, in accordance with some embodiments. FIGS. 2A-2M illustrate a process for forming the integrated circuit package 100 of FIG. 1A, in accordance with some embodiments.

FIG. 2A is a cross-sectional view of a carrier die 110, in accordance with some embodiments. The carrier die 110 is an example of the carrier die 110 of FIG. 1A, at an intermediate stage of processing, in accordance with some embodiments. As described previously, the carrier die 110 can include a semiconductor material. However, in some embodiments, the carrier die 110 can include a dielectric material or other types of materials.

In FIG. 2B, an etching process has been performed to form trenches 162 in the carrier die 110, in accordance with some embodiments. The trenches 162 can be formed by first forming, in conjunction with a photolithography process, a hard mask having a pattern of the trenches 162. The trenches 162 can then be formed with a timed etch in the presence of the hard mask. The timed etch is selected to form the trenches to a selected depth corresponding to a desired thickness of the metal structures 131.

In FIG. 2C, a layer of metal material 164 has been deposited on the carrier die 110 and in the trenches 162, in accordance with some embodiments. The material of the metal layer 164 is the material of the metal structures 131 of FIG. 1A. Accordingly, the metal layer 164 can have materials described previously in relation to the metal structures 131. The metal layer 164 can be deposited by an electrochemical plating (ECP), a physical vapor deposition (PVD), a chemical vapor deposition (CVD), an atomic layer deposition (ALD), or other suitable deposition processes.

In FIG. 2D, a chemical mechanical planarization (CMP) process has been performed on the carrier die 110, in accordance with some embodiments. The CMP process removes the metal layer 164 from the top surface of the carrier die 110. The result is that the top metal structures 131 are formed from the metal layer 164. Furthermore, the top surface of the base material of the carrier die 110 is coplanar with the top surface of the metal structures 131.

FIG. 2E is a cross-sectional view of an integrated circuit die 102 that will be included in the integrated circuit package 100, in accordance with some embodiments. At the stage of processing shown in FIG. 2E, transistors 120 have been formed in the active device region 114 of the integrated circuit die 102. As described previously, the active device area 114 can include one or more semiconductor layers in conjunction with which the transistors 120 are formed.

In FIG. 2F, the front vias 124 and the front side 116 of the integrated circuit die 102 have been formed, in accordance with some embodiments. The front vias 124 can be formed by depositing an interlevel dielectric layer over the transistors 120, patterning the interlevel dielectric layer to form apertures for the front vias 124, and filling the apertures with a metal material of the front vias 124, and performing a CMP process.

In FIG. 2F, the dielectric layers 117, the metal lines 128, and conductive vias 129 of the front side 116 have been formed. Additionally, the top metal structures 130 have been formed. Each layer of metal lines 128 can be formed by depositing a first portion of an interlevel dielectric layer 117, patterning the first portion of the interlevel dielectric layer 117 in the pattern of metal lines 128 to be formed therein, depositing the metal material for the metal lines 128 on the first portion of the interlevel dielectric layer 117, and performing a CMP process. The conductive vias 129 can be formed for each interlevel dielectric layer 117 by depositing a second portion of the interlevel dielectric layer 117 on the metal lines 128, patterning the second portion of the interlevel dielectric layer 117 to form apertures in which conductive vias 129 will be formed, depositing the metal material of the conductive vias 129 in the apertures, and performing a CMP process. This can be repeated until the desired number of layers of metal lines 128 and conductive vias 129 have been formed. Finally, the top metal structures 130 and the top dielectric layer 117 corresponding to a passivation layer can be formed in a similar manner.

In FIG. 2G, the bonding layer 112 has been formed on the front side 116 of the integrated circuit die 102, in accordance with some embodiments. The bonding layer can be formed with a CVD process, an ALD process, a PVD process, or other suitable processes. The bonding layer 112 can have materials and thicknesses described previously.

In FIG. 2H, the carrier die 110 (from the stage of processing shown 2D) has been attached to the top of the integrated circuit die 102 via the bonding layer 112, in accordance with some embodiments. The carrier die 110 is flipped so that the metal structures 131 face and are in proximity to the metal structures 130 of the integrated circuit die 102. At this stage of processing, the carrier die 110 is not yet been thinned.

In FIG. 2I, the integrated circuit die 102 has been flipped so that the carrier die 110 is at the bottom and the active device region 114 is a top, in accordance with some embodiments. A thinning process has been performed to reduce the thickness of the backside of the active device region 114.

In FIG. 2J, the bottom vias 126, the TSVs 127, and the backside 118 have been formed, in accordance with some embodiments. The bottom vias 126 can be formed in a similar manner as the top vias 124 and different materials, as described previously, in accordance with some embodiments. The TSVs 127 can be formed by forming trenches in the active device region to expose selected portions of the metal lines 128 of the front side 116, depositing a metal material in the trenches, and performing a CMP process. The backside 118, including the dielectric layers 119, the metal layers 132, the conductive vias 133, and the bottom metal structures 134 can be formed in a substantially similar manner as described in relation to the front side 116.

In FIG. 2K, a carrier die 168 has been attached to the backside 118 of the integrated circuit die 102, in accordance with some embodiments. The carrier die 168 can be substantially similar to the carrier die 110 at the stage of processing shown in FIG. 2A. The integrated circuit die 102 has been flipped so that the carrier die 110 is at the top again.

In FIG. 2L, a thinning process has been performed to reduce the thickness of the carrier die 110, in accordance with some embodiments. The thinning process can include one or more of a grinding process, an etching process, and a CMP process. The result of the thinning process is that the thickness of the carrier die 110 is the same as the thickness of the metal structures 131. Furthermore, the top surface of the carrier die 110 is substantially coplanar with the top surface of the metal structures 131.

In FIG. 2L, the integrated circuit die 102 has been attached to the interposer 104, in accordance with some embodiments. Attaching an integrated circuit die 102 to the interposer 104 can include electrically connecting the bottom metal structures 134 of the integrated circuit die 102 to the top metal structures 138 of the interposer 104. Furthermore, hybrid bonds 141 are formed at the interface of the metal structures 134 and metal structures 138. As described previously, the hybrid bonds enable a denser pattern of metal structures 134.

In FIG. 2M, the interposer 104 and the integrated circuit die 108 have been attached to the top surface of the substrate 106, in accordance with some embodiments. This results in the integrated circuit package 100 as shown and described in relation to FIG. 1A. The bottom metal structures 150 and the bottom metal structures 161 of the integrated circuit die 108 are connected to the top metal structures 155 by connection structures 154, as described previously. The substrate can utilize a local silicon interposer or an embedded multi-die interconnect bridge (EMIB). This enables the interconnect 159 have a tight pitch between the interposer 104 and the integrated circuit die 108 to satisfy high performance specifications. Other configurations and components can be utilized without departing from the scope of the present disclosure.

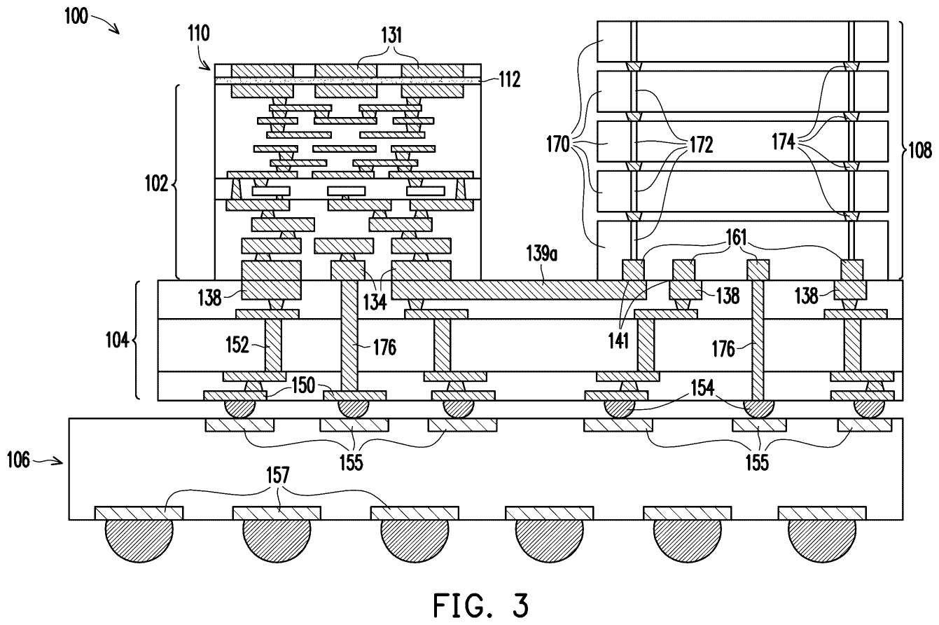

FIG. 3 is an illustration of an integrated circuit package 100, in accordance with some embodiments. The integrated circuit package 100 of FIG. 3 is substantially similar to the integrated circuit package 100 of FIG. 1A in many regards. However, in FIG. 3, the integrated circuit die 108 includes a plurality of individual memory dies 170 stacked together in each including a portion of the memory array 108. The bottom die 170 includes the bottom metal structures 161. The stacked dies are connected by TSVs 172 and external connectors 174. In some embodiments, the integrated circuit die 108 can include up to 16 or more stacked dies 170.

The integrated circuit die 108 is positioned on a top surface of the interposer 104. This is different than the integrated circuit die 108 of FIG. 1A in which the memory die is positioned on a top surface of the substrate 106. The bottom die 170 corresponds to a base die within the integrated circuit die 108. The bottom metal structures 161 of the base die 170 are connected by hybrid bonds to the top metal structures 138 of the interposer 104. Furthermore an electrical connector 139a of the interposer 104 is electrically connected to a bottom metal structure 134 of the integrated circuit die 102 and a bottom metal structure 161 of the base die 170 of the integrated circuit die 108. The interconnection 139a can correspond to a shortest distance between the integrated circuit die 102 and the integrated circuit die 108.

The interposer 104 is an extended area with respect to the interposer 104 of FIG. 1A. Furthermore, the interposer 104 of FIG. 3 includes TSVs 176. One or more TSVs 176 extends from a bottom structure 134 of the integrated circuit die 102 to a bottom metal structure 150 of the interposer 104. One or more TSVs 176 of the interposer 104 extends from a bottom metal structure 161 of the base die 170 to an external interconnection 154 on a bottom surface of the interposer 104.

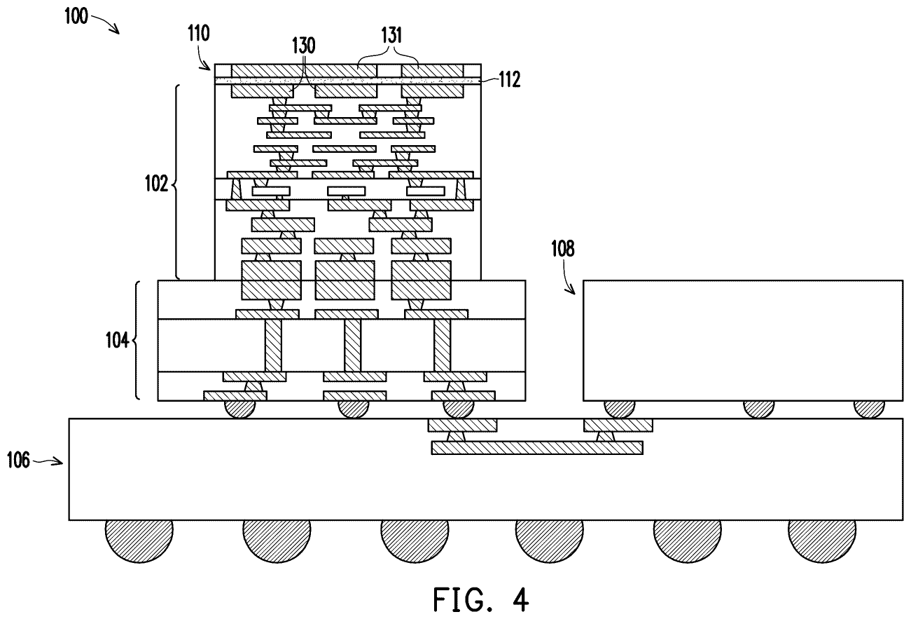

FIG. 4 is an illustration of an integrated circuit package 100, in accordance with some embodiments. The integrated circuit package 100 of FIG. 4 is substantially similar to the integrated circuit package 100 of FIG. 1A, except that the metal structures 131 of the carrier die 110 have a different pattern than the top metal structures 134 of the integrated circuit die 102. In some embodiments, the metal structures 131 of the carrier die 110 have a larger total area than the metal structures 134 of the integrated circuit die 102.

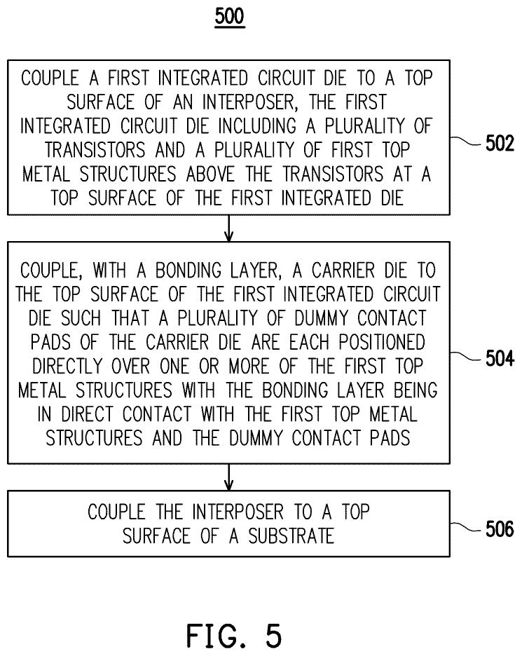

FIG. 5 is a flow diagram of a method 500, in accordance with some embodiments. The method 500 can utilize processes, components, and systems described in relation to the foregoing figures. At 502, the method 500 includes coupling a first integrated circuit die to a top surface of an interposer, the first integrated circuit die including a plurality of transistors and a plurality of first top metal structures above the transistors at a top surface of the first integrated die. One example of a first integrated circuit die is the integrated circuit die 102 of FIG. 1A. One example of transistors of the transistors 120 of FIG. 1A. One example of an interposer is the interposer 104 of FIG. 1A. One example of first top metal structures are the top metal structures 130 of FIG. 1A. At 504, the method 500 includes coupling, with a bonding layer, a carrier die to the top surface of the first integrated circuit die such that a plurality of dummy contact pads of the carrier die are each positioned directly over one or more of the first top metal structures with the bonding layer being in direct contact with the first top metal structures and the dummy contact pads. One example of a bonding layer is the bonding layer 112 of FIG. 1A. One example of a carrier die is the carrier die 110 of FIG. 1A. One example of dummy contact pads of the dummy contact pads 131 of FIG. 1A. At 506, the method 500 includes coupling the interposer to a top surface of a substrate. One example of a substrate is the substrate 106 of FIG. 1A.

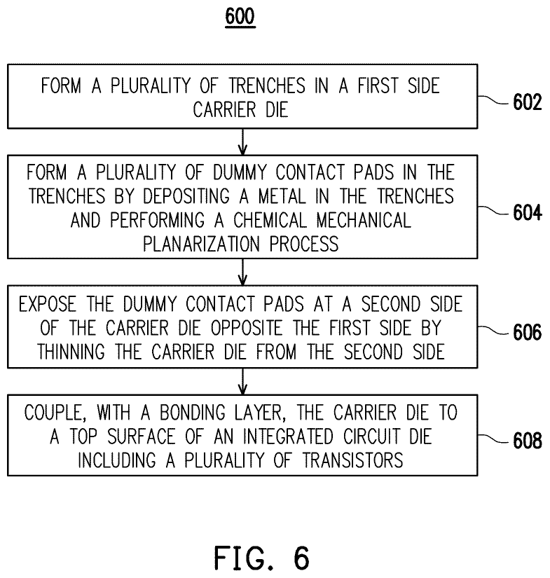

FIG. 6 is a flow diagram of a method 600, in accordance with some embodiments. The method 600 can utilize processes, components, and systems described in relation to the foregoing figures. At 602, the method 600 includes forming a plurality of trenches in a first side carrier die. One example of the carrier die is the carrier die 102 of FIG. 2A. One example of trenches are the trenches 162 of FIG. 2B. At 604, the method 600 includes forming a plurality of dummy contact pads in the trenches by depositing a metal in the trenches and performing a chemical mechanical planarization process. One example of a metal is the metal 164 of FIG. 2C. One example of dummy contact pads are the dummy contact pads 131 of FIG. 2D. At 606, the method 600 includes exposing the dummy contact pads at a second side of the carrier die opposite the first side by thinning the carrier die from the second side. At 608, the method 600 includes coupling, with a bonding layer, the carrier die to a top surface of an integrated circuit die including a plurality of transistors. One example of a bonding layer is the bonding layer 112 of FIG. 1A. One example of an integrated circuit die is the integrated circuit die 102 of FIG. 1A. One example of transistors is the transistors 120 of FIG. 1A.

Embodiments of the present disclosure provide an integrated circuit package with improved heat dissipation. The integrated circuit package includes an integrated circuit die positioned on top of an interposer. The interposer, in turn, is positioned on a substrate. One or more memory dies are also positioned on either the interposer or the substrate. The integrated circuit die includes a plurality of transistors that, in operation, may generate a large amount of heat. The integrated circuit die includes front side metal interconnection structures includes conductive vias and metal lines above the transistors. The integrated circuit die includes backside metal interconnection structures including conductive vias and metal lines below the transistors. The front side of backside metal interconnection structures are electrically connected by one or more through vias. The front side interconnection structures include a top metal layer patterned as a plurality of contact pads. In order to facilitate heat dissipation, the package includes a carrier die and coupled to a top surface of the front side of the integrated circuit. The carrier die includes a plurality of dummy contact pads positioned directly above the contact pads of the front side of the integrated circuit die. The carrier die is thinned so that the thickness of the carrier die corresponds to the thickness of the dummy contact pads. A nonconductive bonding layer is positioned between the integrated circuit die and the carrier die.

The presence of the carrier die and the dummy contact pads results in greatly improved heat dissipation. Heat from the transistors of the integrated circuit die flows upward through the front side metal interconnections to the contact pads. The heat flows to the dummy contact pads of the carrier die and is effectively dissipated from the dummy contact pads. Heat also dissipates to a lesser extent through the backside metal interconnections. However, the presence of the front side interconnections and the dummy contact pads of the carrier die results in highly effective upward heat dissipation from the transistors. This reduces the possibility of damage to components of the package. This also provides higher performance for the transistors and other components of the package. This also results in higher package yields and fewer scrapped packages.

In some embodiments, an integrated circuit package includes a substrate and a first integrated circuit die above the substrate. The first integrated circuit die includes a plurality of transistors, a plurality of first top metal structures above the transistors, and a plurality of first bottom metal structures below the transistors. The package includes a carrier die bonded to a top surface of the first integrated circuit die and including a plurality of dummy contact pads each positioned directly over one or more of the first top metal structures. The package includes a bonding layer between the carrier die and the first integrated circuit die and in direct contact with the top metal structures and the dummy contact pads.

In some embodiments, a method includes coupling a first integrated circuit die to a top surface of an interposer. The first integrated circuit die includes a plurality of transistors and a plurality of first top metal structures above the transistors at a top surface of the first integrated die. The method includes coupling, with a bonding layer, a carrier die to the top surface of the first integrated circuit die such that a plurality of dummy contact pads of the carrier die are each positioned directly over one or more of the first top metal structures with the bonding layer being in direct contact with the first top metal structures and the dummy contact pads. The method includes coupling the interposer to a top surface of a substrate.

In some embodiments, a method includes forming a plurality of trenches in a first side carrier die and forming a plurality of dummy contact pads in the trenches by depositing a metal in the trenches and performing a chemical mechanical planarization process. The method includes exposing the dummy contact pads at a second side of the carrier die opposite the first side by thinning the carrier die from the second side and coupling, with a bonding layer, the carrier die to a top surface of an integrated circuit die including a plurality of transistors.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. An integrated circuit package, comprising:
a substrate;
a first integrated circuit die above the substrate and including:
a plurality of transistors;
a plurality of first top metal structures above the transistors; and
a plurality of first bottom metal structures below the transistors;
a carrier die bonded to a top surface of the first integrated circuit die and including a plurality of dummy contact pads each positioned directly over one or more of the first top metal structures; and
a bonding layer between the carrier die and the first integrated circuit die and in direct contact with the first top metal structures and the dummy contact pads.

2. The integrated circuit package of claim 1, wherein the carrier die has a same vertical thickness as the dummy contact pads.

3. The integrated circuit package of claim 1, wherein the dummy contact pads and the first top metal structures have a same layout.

4. The integrated circuit of claim 1, wherein the dummy contact pads have a different layout than the first top metal structures.

5. The integrated circuit package of claim 4, wherein the dummy contact pads have a greater collective layout area than the first top metal structures.

6. The integrated circuit package of claim 1, comprising:
an interposer positioned on a top surface of the substrate and including:
a semiconductor layer;
second top metal structures above the semiconductor layer; and
a plurality of through silicon vias extending through the semiconductor layer.

7. The integrated circuit package of claim 6 wherein the first integrated circuit die is positioned on a top surface of the interposer, wherein the first bottom metal structures are each bonded to a respective second top metal structure of the interposer with a hybrid bond.

8. The integrated circuit package of claim 7, comprising a second integrated circuit die including a memory array and positioned on the substrate laterally adjacent to the interposer.

9. The integrated circuit package of claim 8, comprising a second integrated circuit die including a memory array and positioned on the top surface of the interposer and including a plurality of second bottom metal structures each bonded to a respective second top metal structure of the interposer by a hybrid bond.

10. The integrated circuit package of claim 9, wherein the second integrated circuit die includes a stack of memory dies.

11. A method, comprising:
coupling a first integrated circuit die to a top surface of an interposer, the first integrated circuit die including a plurality of transistors and a plurality of first top metal structures above the transistors at a top surface of the first integrated die;
coupling, with a bonding layer, a carrier die to the top surface of the first integrated circuit die such that a plurality of dummy contact pads of the carrier die are each positioned directly over one or more of the first top metal structures with the bonding layer being in direct contact with the first top metal structures and the dummy contact pads; and
coupling the interposer to a top surface of a substrate.

12. The method of claim 11, wherein coupling the first integrated circuit die to the top surface of the interposer includes performing a first hybrid bonding process that bonds each of a plurality of first bottom metal structures of the first integrated circuit die to a corresponding second top metal structure of the interposer.

13. The method of claim 12, comprising coupling a second integrated circuit die to the top surface of the interposer.

14. The method of claim 13, wherein coupling the second integrated circuit die to the top surface of the interposer includes bonding each of a plurality of second bottom metal structures of the second integrated circuit die to a corresponding second top metal structure of the interposer with either the first hybrid bonding process or a second hybrid bonding process.

15. The method of claim 11, wherein the carrier die has a same total thickness as the dummy contact pads.

16. The method of claim 11, wherein coupling the interposer to the top surface of the substrate includes coupling each of a plurality of micro bumps between a respective bottom metal structure of the interposer and a respective second top metal structure of the substrate.

17. The method of claim 11, wherein the interposer includes a plurality of through silicon vias.

18. A method, comprising:
forming a plurality of trenches in a first side of a carrier die;
forming a plurality of dummy contact pads in the trenches by depositing a metal in the trenches and performing a chemical mechanical planarization process;
exposing the dummy contact pads at a second side of the carrier die opposite the first side by thinning the carrier die from the second side; and
coupling, with a bonding layer, the carrier die to a top surface of an integrated circuit die including a plurality of transistors.

19. The method of claim 18, wherein the bonding layer is a dielectric layer.

20. The method of claim 18, wherein after coupling the carrier die to the integrated circuit die each of the dummy contacts is positioned directly over one or more top metal structures at a top surface of the integrated circuit.
